(19) United States
(12) Patent Application Publication
(10) Pub. No.: US 2020/0245448 A1
(43) Pub. Date: Jul. 30, 2020

(54) PRINTED CIRCUIT BOARD AND APPARATUS INCLUDING THE SAME

(71) Applicant: SAMSUNG ELECTRONICS CO., LTD., Suwon-si, Gyeonggi-do (KR)

(72) Inventor: Yong Hee CHO, Suwon-si, Gyeonggi-do (KR)

(21) Appl. No.: 16/652,243

(22) PCT Filed: Sep. 28, 2018
(86) PCT No.: PCT/KR2018/011603

§ 371 Date: Mar. 30, 2020

(30) Foreign Application Priority Data
Sep. 29, 2017 (KR) 10-2017-0126992

(51) Int. Cl. H05K 1/02; H05K 1/18; H05K 1/11

(52) U.S. Cl. CPC H05K 1/0218; H05K 1/181; H05K 1/115; H05K 2201/09227; H05K 2201/10159; H05K 2201/10522; H05K 2201/09327; H05K 2201/093

(57) ABSTRACT

A printed circuit board may comprise a first layer in which a first signal transmission path is formed, a second layer disposed in one surface direction of the first layer and including a first ground for providing a return current path for a signal transmitted from the first layer, a third layer in which a second signal transmission path is formed and a fourth layer disposed in the other surface direction of the third layer and including a second ground for providing a return current path for a signal transmitted from the third layer.

### TECHNICAL FIELD

Embodiments of the disclosure relate to a printed circuit board and an apparatus including the same.

### BACKGROUND ART

A printed circuit board is a plate on which copper wiring is printed so that at least one circuit element (for example, a semiconductor chip, capacitor, relay, diode, etc.) necessary for driving an electronic device can be installed. At least one circuit element is installed in the copper wiring to be electrically connected to other circuit elements to transmit and receive signals, and/or may be electrically connected to an external power supply to receive power for operation.

Such printed circuit boards are used in various electronic devices. For example, the printed circuit boards are embedded in various home appliances such as televisions and refrigerators, various portable devices, computer devices, vehicles, industrial machines and robots, rockets and satellites, and various devices operated to provide performance.

The printed circuit board may have a laminated structure in which a plurality of conductive plates are overlapped. In this case, the printed circuit board may be implemented by inserting an insulator between the plurality of conductive plates. The plurality of conductive plates is electrically connected through vias formed in the insulator.

### DISCLOSURE

### Technical Problem

An object of the present disclosure is to provide a printed circuit board and a device including the printed circuit board for enabling a system to operate stably even in a system using a high speed circuit device, for example, a memory or a processor.

### Technical Solution

In order to solve the above problems, a printed circuit board and an apparatus including the same are provided.

In accordance with an aspect of the disclosure, a printed circuit board may comprise a first layer in which a first signal transmission path is formed; a second layer disposed in one surface direction of the first layer and including a first ground for providing a return current path for a signal transmitted from the first layer; a third layer in which a second signal transmission path is formed; and a fourth layer disposed in the other surface direction of the third layer and including a second ground for providing a return current path for a signal transmitted from the third layer.

The printed circuit board may further comprise a plurality of circuit elements installed in the first layer; and at least one of a first power supplier installed in the first layer for supplying power to at least one of the plurality of circuit elements; a second power supplier installed in the third layer for supplying power to at least one of the plurality of circuit elements; and a third power supplier installed in the fourth layer for supplying power to at least one of the plurality of circuit elements.

The first power supplier may have a flat plate shape of a predetermined pattern. All or a portion of the first power supplier may be disposed between at least two of the plurality of first circuit elements.

The area of the first power supplier may be the same as the area of the first ground or smaller than the area of the first ground.

The area of the first power supplier may correspond to a ratio of distance between the first layer and the second layer and distance between the second layer and the fourth layer.

The first power supplier may include a plurality of power suppliers spaced apart from each other, and the plurality of power suppliers may be electrically connected to each of the corresponding plurality of circuit elements to supply power to each of the plurality of circuit elements.

At least two of the first power supplier, the second power supplier, and the third power supplier may be electrically connected to each other.

The size of the second power supplier may be equal to or smaller than the size of the fourth layer.

The first power supplier may be installed to be exposed to the outside in the other surface direction of the first layer.

The plurality of circuit elements may include a transmitting element for transmitting the signal; and a receiving element receiving the signal transmitted from the transmitting element.

The plurality of circuit elements may include a processor chip and a memory chip.

The memory chip may have an operation speed of 3000 Mbps or more.

The first layer and the third layer may be electrically connected and the signal is transmitted from the first layer to the third layer.

The signal transmitted from the first layer to the third layer may be transmitted from the third layer to the first layer after passing the second signal transmission path.

The printed circuit board may include a dielectric disposed between the first layer and the third layer.

In accordance with another aspect of the disclosure, an electronic device may comprise a first circuit element, a second circuit element capable of receiving electrical signals from the first circuit element, and a printed circuit board on which the first circuit element and the second circuit element are mounted, wherein the printed circuit board may comprise a first layer in which a first signal transmission path is formed; a second layer disposed in one surface direction of the first layer and including a first ground for providing a return current path for a signal transmitted from the first layer; a third layer in which a second signal transmission path is formed; and a fourth layer disposed in the other surface direction of the third layer and including a second ground for providing a return current path for a signal transmitted from the third layer.

The printed circuit board may be installed at least one of the first layer, the third layer, and the fourth layer, and may further include a power supplier that supplies power to at least one of the first circuit element and the second circuit element.

### Advantageous Effects

According to the above-described printed circuit board and the apparatus including the same, the system can be stably operated with high reliability even in a circuit element having a high operating speed, for example, a memory or a processor.

According to the above-described printed circuit board and the apparatus including the same, a system requiring at least six layers of the printed circuit boards with only four layers of the printed circuit boards can be stably operated without malfunction.

According to the above-described printed circuit board and the apparatus including the same, when using a memory having a high operating speed of 3000 Mbps or more, since only four layers of the printed circuit boards can be properly operated, there is no need to employ six layers of the printed circuit boards.

According to the above-described printed circuit board and the apparatus including the same, the power supplier (power plane) for supplying power to the circuit element can be freely designed in at least one of the plurality of signal layers, thereby allowing the space in the printed circuit board to be used more efficiently.

According to the above-described printed circuit board and the apparatus including the same, since the manufacturing cost of the printed circuit boards becomes relatively inexpensive, production costs can be reduced. In addition, the thickness of the printed circuit board is relatively thin, so that the internal structure of the electronic device employing the printed circuit board can be more variously and easily designed.

### DESCRIPTION OF DRAWINGS

FIG. 1 is a perspective view of one embodiment of a printed circuit board.

FIG. 2 is a cross-sectional view of one embodiment of a printed circuit board.

FIG. 3 is a cross-sectional view of a conventional printed circuit board having a power plane formed in a fourth layer and a flow of signals.

FIG. 4 is a diagram illustrating a signal flow in an embodiment of a printed circuit board in which a fourth layer is implemented as a ground layer.

FIG. 5 is a diagram illustrating an example of signals that can be transmitted on a printed circuit board.

FIG. 6 is a diagram for describing an example in which noise of a signal transmitted along the printed circuit board of FIG. 5 is eliminated.

FIG. 7 is a graph comparing s-parameters between the above-described printed circuit board and a conventional printed circuit board.

FIG. 8 is a first diagram for describing a conventional printed circuit board having a power layer formed on a fourth layer.

FIG. 9 is a second diagram for describing a conventional printed circuit board having a power layer formed on a fourth layer.

FIG. 10 shows a conventional power supply layer.

FIG. 11 is a plan view showing an example of a power supply unit formed in a first layer.

FIG. 12 is a diagram for describing an electrical connection between a power supply unit of a first layer and a third layer.

FIG. 13A is a diagram illustrating a first example of a power supplier.

FIG. 13B is a diagram illustrating a second example of a power supplier.

FIG. 14 is a diagram for describing impedance between a power plane and a ground.

FIG. 15 is a cross-sectional view of a modification of a printed circuit board.

FIG. 16 is a sectional view of another modification of a printed circuit board.

FIG. 17 is a sectional view of another modification of a printed circuit board.

FIG. 18 is a plan view of an example of a conventional printed circuit board.

FIG. 19 is a rear view of an example of a conventional printed circuit board.

FIG. 20 is a plan view of one embodiment of the above-described printed circuit board.

FIG. 21 is a rear view of one embodiment of the above-described printed circuit board.

FIG. 22 is a plan view of another example of a conventional printed circuit board.

FIG. 23 is a rear view of another example of a conventional printed circuit board.

FIG. 24 is a plan view of one embodiment of the above-described printed circuit board.

FIG. 25 is a rear view of one embodiment of the above-described printed circuit board.

### BEST MODE

### Mode for Invention

Like reference numerals refer to like elements throughout the specification unless otherwise specified. As used herein, the term “part” is added and may be implemented in software or hardware. According to an exemplary embodiment, the term ‘part’ may be implemented as one component or one ‘part’ may be implemented as a plurality of components.

Throughout the specification, when an element is referred to as being “connected to” another element, it may be directly or indirectly connected to the other element and the “indirectly connected to” includes being connected to the other element via a wireless communication network.

Also, it is to be understood that the terms “include” and “have” are intended to indicate the existence of elements disclosed in the specification, and are not intended to preclude the possibility that one or more other elements may exist or may be added.

In this specification, the terms “first,” “second,” etc. are used to distinguish one component from other components and, therefore, the components are not limited by the terms.

An expression used in the singular form encompasses the expression of the plural form, unless it has a clearly different meaning in the context.

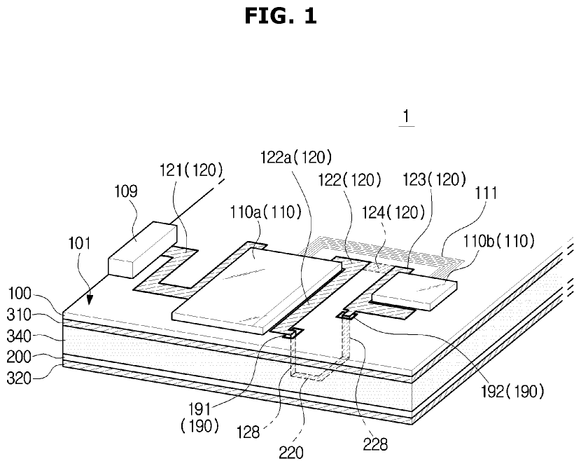

Hereinafter, various embodiments of the printed circuit board will be described with reference to FIGS. 1 to 18.

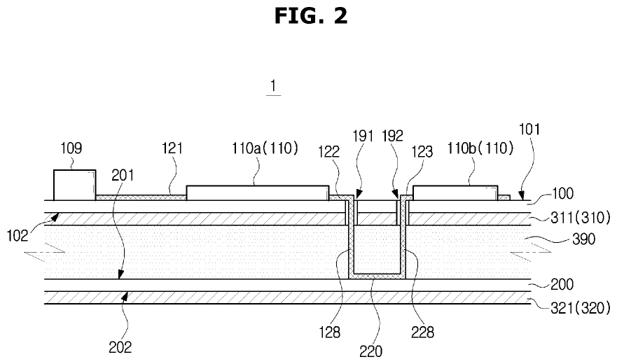

FIG. 1 is a perspective view of one embodiment of a printed circuit board, and FIG. 2 is a cross-sectional view of one embodiment of a printed circuit board.

Referring to FIGS. 1 2, a printed circuit board 1 according to the exemplary embodiment may include a plurality of stacked layers 100, 200, 310, and 320. In this case, the printed circuit board 1 may have the four layers 100, 200, 310, and 320 sequentially stacked on each other, and the four layers may include at least one of circuit elements 109 and 110, and includes the first layer 100, the second layer 310 formed in contact with or adjacent to the first layer 100, the third layer 200 through which signals are transmitted, the fourth layer 320 formed in contact with or adjacent to the third layer 200.

In one embodiment, the first layer 100 (which may be referred to as a signal layer since the signal is transmitted) includes one surface 101 that is exposed to the outside and other surface 102 opposite to the surface, and at least one of the circuit elements 109 and 110 is formed on the exposed one surface 101. In addition, the first layer 100 may include a power supplier 120 (hereinafter, referred to as ‘first power supplier’) for supplying power to at least one of the circuit elements 109 and 110, and at least one signal line 111 may be further formed to transmit a signal between the at least one circuit elements 109 and 110. In addition, the first layer 100 may include the first power supplier for supplying power to at least one of the circuit elements 109 and 110, and the at least one signal line 111 may be further formed to transmit a signal between the at least one circuit elements 109 and 110.

The at least one circuit element 110 may be disposed in a predetermined pattern on the one surface 101 of the first layer 100. In this case, the at least one circuit element 110 is provided such that all or part of the at least one circuit element 110 is exposed to the outside of the first layer 100.

The at least one circuit element 110 may include an integrated circuit. The integrated circuit 110 may be implemented using a semiconductor device. The integrated circuit may include, for example, a processor 110a capable of performing various arithmetic and control processes, and in addition, it may further include a memory device 110b afor storing a variety of data in the form of an electrical signal.

The processor 110a refers to an apparatus/device capable of performing a predetermined calculation and/or control processing that can be implemented using one or more semiconductor chips and related components. The processor 110a may be, for example, a central processing unit (CPU), a micro controller unit (MCU), a microcomputer (Micom), an application processor (AP), an electronic device, an electronic control unit (ECU) and/or other electronic device capable of generating various arithmetic processing and control signals.

The memory device 110b is electrically connected to the processor 110a and is provided to receive an electrical signal from the processor 110a and/or to transmit an electrical signal to the processor 110a.

The memory device 110b may include RAM and ROM. The RAM may include, for example, DRAM, Dynamic RAM, SRAM, Static RAM, and/or Non-volatile RAM.

Here, the SRAM may include synchronous DRAM (SDRAM), such as DDR SDRAM (DDR SDRAM, Double Data Rate SDRAM). The DDR SDRAM may be capable of including, for example, low power DDR SDRAM (LPDDR SDRAM, Low Power DDR SDRAM, and the included memory can be referred to as LPDDR memory, mobile DDR memory or mDDR memory). The low power DDR SDRAM may be, for example, LPDDR1, LPDDR2, LPDDR3, LPDDR4, LPDDR4x or other low power DDR memory. The ROM may include mask ROM, Programmable ROM (PROM), Erasable PROM (EPROM) and/or Electrically EPROM (EEPR), or the like. In addition, the memory device 110b may include flash memory. The memory device 110b may include various types of memory devices that may be installed in the first layer 100 in addition to the example to be disclosed.

The at least one circuit element may further comprise the power receiver 109. The power receiver 109 is electrically connected to a power source external to the printed circuit board 1 to receive power from the external power source. The power receiver 109 may include at least one terminal to which an external cable can be mounted and installed. The power received by the power receiver 109 is delivered to each component in the printed circuit board 1, for example the processor 110a and the memory element 110b, via the first power supplier 120 and/or further via a second power supplier 220.

In addition, the at least one circuit element 110 may further include a capacitor, an inductor, a diode, a transistor, a light tube, and/or an amplifier that may be installed on the first layer 100. These circuit elements 110 may be installed on at least one position of the first layer 100 according to a designer's choice. At least one of these circuit elements 110 may be electrically connected to at least one of the power receiver 109, the processor 110a, and the memory element 110b described above. In addition, at least one of these circuit elements 110 may be electrically connected to the first power supplier 120 to apply the power required for operation from the first power supplier 120.

The first power supplier 120 may be formed in at least one of the one surface 101 and the other surface 102 of the first layer 100 in a predetermined pattern.

The first power supplier 120 may be implemented in whole or in part using a plate-shaped metal plate, or may be implemented using a metal wire. In addition, all or part of the first power supplier 120 may be formed on the one surface 101 of the first layer 100 to be exposed to the outside. In this case, all or part of the first power supplier 120 may be applied by a predetermined coating material, for example, PSR ink, in order to prevent damage to the first power supplier 120 or defects such as a solder bridge.

According to an embodiment, the first power supplier 120 is provided corresponding to the second layer 320 or the portion used as the ground of the second layer 320. For example, the first power supplier 120 may be installed in the first layer to have an area equal to the area of the portion used as the ground of the second layer 320 or be smaller than the area of the second layer 320 or the area of the portion used as the ground of the second layer 320. This is because the area of the first power supplier 120 is larger than the portion used as the ground of the second layer 320, thereby preventing the transmission of the signal between the two devices.

The first power supplier 120 enables electricity to be connected between the power receiver 109 and the at least one circuit element 110, for example, the processor 110a and/or the memory 110b formed in the first layer 100, and supplies power to the components 110a and 110b.

For example, a portion 121 (hereinafter, referred to as ‘first portion’) of the first power supplier 120 is formed in a predetermined pattern in a region existing between the power receiver 109 of the first layer 100 and the processor 110a. Another portion 122 (hereinafter, referred to as ‘second portion’) is formed in the first layer 100 in contact with all or a part of the processor 110a and is provided to supply power received by the power receiver 109 to the processor 110a. FIGS. 1 and 2 illustrate an embodiment in which the power receiver 109 and the processor 110a are directly connected, but this is an exemplary. According to an embodiment, it is also possible for another at least one circuit element, such as a DC-DC converter, to be further mounted and formed between the power receiver 109 and the processor 110a. The processor 110a operates using the power supplied through the first portion 121 and the second portion 122.

According to an embodiment, at least one via hole 190 may be formed in a printed circuit board 9. The via hole 190 is formed through the first layer 100 and the second layer 310. The via hole 190 electrically connects the first layer 100 and the third layer 200 so that an electrical signal is transmitted from the first layer 100 to the third layer 200 and/or from the third layer 200 to the first layer 100.

A portion of the first power supplier 120, and a portion of the second portion 122, for example one end 122a of the second portion 122, extends into at least one via hole 191 (hereinafter, referred to as ‘first via hole’) and, it may be designed to be electrically connected to the power supplier 220 of the third layer 200 through a metal plate or a metal wire 128 provided in the first via hole 191.

According to an embodiment, another portion 123 (hereinafter, referred to as ‘third portion’) of the first power supplier 120 may be further formed in the first layer 100. The third portion 123 is connected to at least one other via hole 192 (hereinafter, referred to as ‘second via hole’) and at least one circuit element, for example, the memory element 110b, to transmit power transmitted through the second via hole 192 to the memory device 110b. In this case, the second via hole 192 may be electrically connected to the second power supplier 220 through a conductor 228 provided in the second via hole 192. In this case, the memory device 110b may be supplied with power through the power receiver 109, the first portion 121, the second portion 122, the second power supplier 220, and the third portion 123 formed in the first layer 100. In addition, the memory device 110b is electrically connected to the processor 110a through the first portion 121, the second portion 122, the second power supplier 220, and the third portion 123. Accordingly, an electrical signal may be transmitted from the processor 110a to the memory element 110b, or conversely, an electrical signal may be transmitted from the memory element 110b to the processor 110a.

In addition, the signal lines 111 of the first layer 100 may be electrically connected to the via holes 191 and 192. In this case, the signal lines 111 of the first layer 100 and the signal lines (not shown) of the third layer 200 may be electrically connected through the via holes 191 and 192 to transmit signals to each other.

FIGS. 1 and 2 show the memory device 110b being supplied power through the power receiver 109, the first portion 121, the second portion 122, the conductors 128 and 228, the second power supplier 220 and the third portion 123 of the third layer 200, but this is only an example. According to an exemplary embodiment, another portion 124 (hereinafter, referred to as ‘fourth portion’) connecting the second portion 122 and the third portion 123 may be further formed in the first layer 100. In this case, the memory device 110b may be supplied with power only through the power receiver 109, the first portion 121, the second portion 122, the fourth portion 124, and the third portion 123 formed in the first layer 100. In other words, the power supplied by the power receiver 109 is transferred to the memory device 110b via the power receiver 109, the first portion 121, the second portion 122, the fourth portion 124, and the third portion 123 sequentially. In addition, the memory device 110b is electrically connected to the processor 110a through the first portion 121, the second portion 122, the fourth portion 124, and the third portion 123. An electrical signal may be received from the processor 110a or an electrical signal may be transmitted to the processor 110a.

More detailed information about the first power supplier 120 will be described later. The signal line 111 may be formed on the at least one surface 101 of the first layer 100. The signal line 111 may be formed on at least one surface of the first layer 100 in various patterns according to the designer's selection and intention. In some embodiments, the signal line 111 may be formed adjacent to the first power supplier 120.

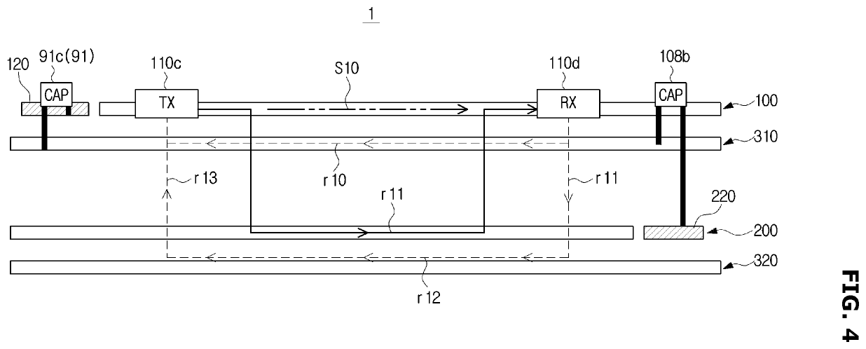

According to an embodiment, at least one decoupling capacitor (108a and 108b of FIG. 4) may be further installed on the one surface 101 of the first layer 100. At least one of the decoupling capacitors 108a and 108b is used for decoupling between circuit elements or each of the layers. Specifically, for example, at least one of the decoupling capacitors 108a and 108b may be used for decoupling between the ground layers 310 and 320 and the power suppliers 120 and 220. At least one of the decoupling capacitors 108a and 108b may be omitted, depending on the embodiment.

Referring to FIGS. 1 and 2, the second layer 310 is formed in the direction of the other surface 102 of the first layer 100. The second layer 310 may be formed in direct contact with or in proximity to the other surface 102 of the first layer 100.

The second layer 310 (also referred to as ‘ground layer’ because a ground is formed) may include a ground 311 (hereinafter, referred to as ‘first ground’) that provides a return current path for the electrical signals transmitted from the first layer 100. In other words, when an electrical signal is transmitted from the processor 110a to the memory element 110b, the first ground 311 of the second layer 310 returns the electrical signal from the memory element 110b to the processor 110a. The return current path may be provided corresponding to the first power supplier 120 formed in the first layer 100. According to an embodiment, the first ground 311 of the second layer 310 may be designed to provide a return current path even for the electrical signal transmitted from the third layer 200.

The first ground 311 may be formed in approximately all areas of the second layer 210, or may be formed in only a few areas, for example, as shown in FIG. 2.

According to one embodiment, as shown in FIG. 2, the first ground 311 may be formed in substantially all portions of the second layer 310. That is, most of the second layer 310 is available in the area as the ground.

According to another embodiment, the first ground (not shown) may be formed only in a portion of all the regions of the second layer 310. In other words, only a portion of the second layer 310 provides a return current path for the electrical signal transmitted from the first layer 100, and it is also possible that the other part is arranged so as not to provide such a return path. In this case, the size of the first ground may be smaller than the overall size of the first layer 100. When the first ground is formed only in some areas, the first ground may be provided to correspond to the signal line 111 or a power supplier 420 of the first layer 100. Specifically, for example, the first ground may be provided on at least one position of the second layer 310 corresponding to the position of the signal line 111 or the power supplier 420. In other regions where the first ground is not formed, for example, the power supplier 420 may be formed or other circuit components may be formed.

As shown in FIG. 1, the second layer 310 may be provided in the same shape and/or the same size as the first layer 100. Alternatively, it may be provided in a different shape and/or a different size than the first layer 100.

One surface of the second layer 310 faces toward the first layer 100, and the other surface faces toward the third layer 200.

The third layer 200 (which may be referred to as a signal layer because a signal may be transmitted) has the one surface 201 facing the second layer 310 and the other surface 202 facing the fourth layer 320.

In example embodiments, a signal line (not shown) and/or at least one circuit element (not shown) may be further formed on the third layer 200. For example, in the third layer 200, signal lines may be formed similarly to the first layer 100, and may also further include a processor, a memory device, a capacitor, an inductor, a diode, a transistor, and a display connected to the signal lines, tubes and/or amplifiers. The signal line of the third layer 200 may be electrically connected to the signal line 111 of the first layer 100 as needed.

As illustrated in FIG. 2, at least the one other power supplier 220 capable of transmitting an electrical signal may be further formed in the third layer 200.

Like the first power supplier 120, the second power supplier 220 may be implemented in whole or in part using a metal plate or a metal wire. In addition, all or part of the second power supplier 220 may be formed on one surface 201 of the third layer 200, in which case all or part of the second power supplier 220 may be exposed toward a dielectric 390. In addition, all or part of the second power supplier 220 may be coated with a material such as PSR ink.

The second power supplier 220 may be electrically connected to the metal plate or the metal line 128 provided in the first via hole 191 and the metal plate or the metal line 128 provided in the second via hole 192, respectively. Accordingly, the power supplied from the power receiver 109 or the electrical signal transmitted from the circuit elements 110a and 110b may pass through the second power supplier 220.

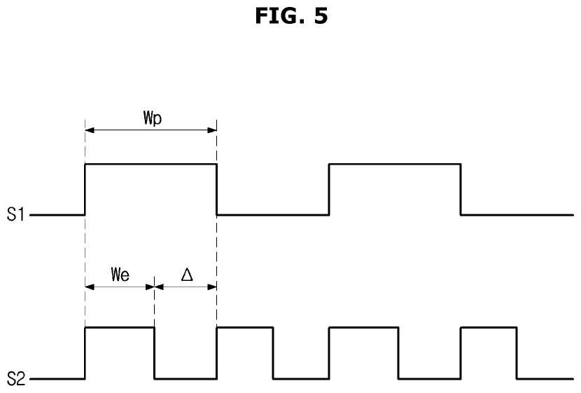

As shown in FIG. 5, the second power supplier 220 may be installed on the one surface 201 of the third layer 200 in an arbitrary pattern selected by the designer. In this case, the installation pattern of the second power supplier 220 may be variously determined according to the arrangement pattern of the circuit elements 110a and 110b or the transmission path of the electrical signal.

The fourth layer 320 (which may be referred to as a ground layer because the ground is formed) may include a ground 321 (hereinafter, referred to as ‘second ground’) for providing a return current path for an electrical signal transmitted from at least one of the first layer 100 and the third layer 200. For example, when an electrical signal is transmitted from the processor 110a to the memory device 110b through the second power supplier 220, the second ground 321 of the fourth layer 320 may provide a return current path corresponding to the second power supplier 220 from the memory device 110b to the processor 110a.

According to an embodiment, similar to the second layer 310, the second ground 321 may be formed in all portions of the fourth layer 320. In addition, according to another embodiment, the second ground (not shown) may be formed only in a portion of the fourth layer 320. When the second ground is formed only in some regions, the second ground may be provided so that the formed position corresponds to the position where the second power supplier 220 of the third layer 200 or the signal line formed in the third layer 200 is installed.

The fourth layer 320 may be provided with the same shape and/or the same area as the third layer 200 as shown in FIG. 1. Alternatively, the fourth layer 320 may be provided with a different shape and/or different area than the third layer 200. According to an embodiment, the area of the second ground 321 of the fourth layer 320 may be greater than or equal to the area of the second power supplier 220 of the third layer 200 for proper transmission of the signal.

In addition, at least one decoupling capacitor may be further installed on one surface of the fourth layer 320 in the same or partially modified manner as in the case of the first layer 100.

In some embodiments, the dielectric 390 may be further provided between the second layer 310 and the third layer 200. The dielectric 390 may separate the second layer 310 and the third layer 200 to prevent a malfunction in the signal transmission of the third layer 200. In addition, the dielectric 390 may protect a component installed in the third layer 200, for example, the second power supplier 220.

Hereinafter, the flow of signals in the conventional printed circuit board 9 and the above-described printed circuit board 1 will be described.

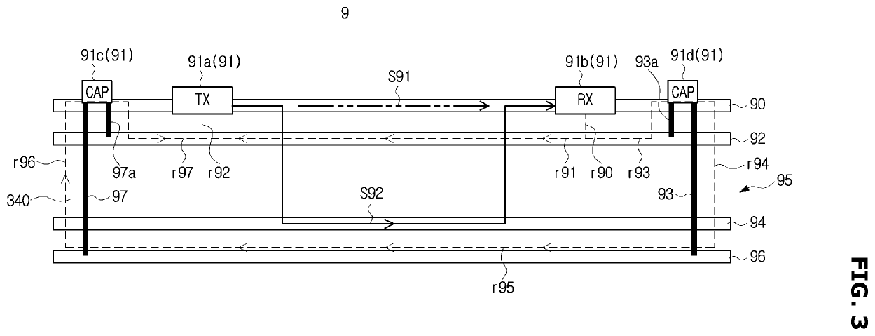

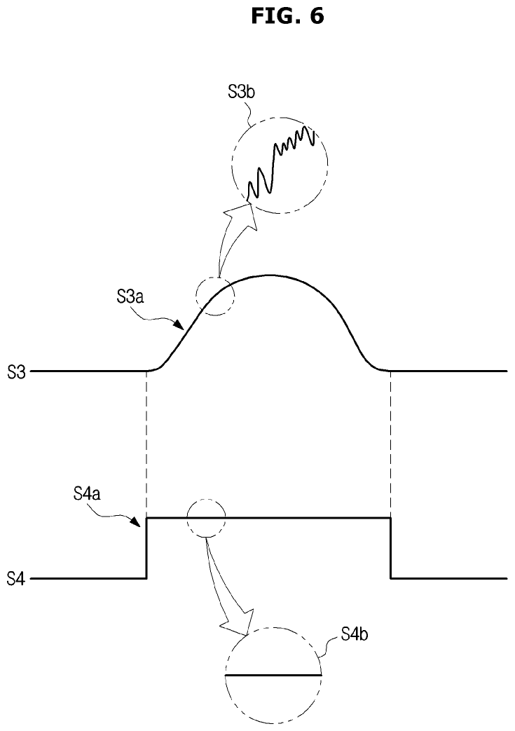

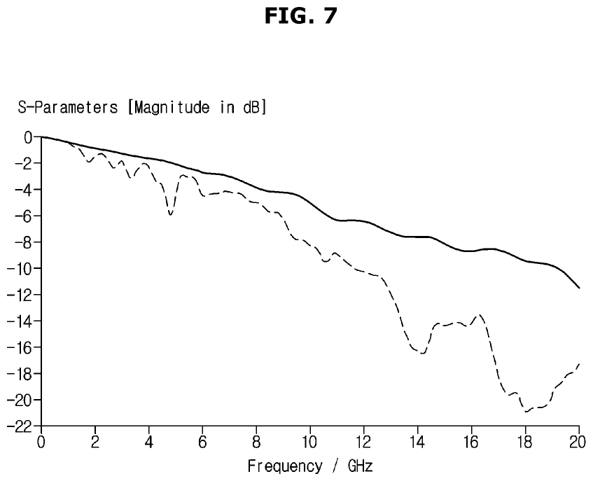

FIG. 3 is a cross-sectional view of a conventional printed circuit board having a power plane formed in a fourth layer and a signal flow, which illustrates a printed circuit board on which a conventional memory is mounted. FIG. 4 is a diagram illustrating a signal flow in an embodiment of a printed circuit board in which a fourth layer is implemented as a ground layer. FIG. 5 is a view showing an example of signals that can be transmitted from a printed circuit board, and FIG. 6 is a diagram for describing an example in which noise of a signal transmitted along the printed circuit board of FIG. 5 is eliminated. In FIG. 6, an x-axis denotes a frequency of the signal and a y-axis denotes the magnitude of an S-parameter. FIG. 7 is a graph comparing s-parameters between the above-described printed circuit board and a conventional printed circuit board.

As shown in FIG. 3, the conventional four-layer printed circuit board 9 is implemented as a plurality of layers, and the plurality of layers may include upper signal layers having various components 90a and 90b installed on one surface thereof (hereinafter, referred to as ‘upper signal layer’), a ground layer 92 disposed in contact with or adjacent to the other surface of a signal layer 90, another signal layer 94 (hereinafter, referred to as ‘lower signal layer’) facing the other side of the ground layer 92 and a dielectric layer 95 spaced apart from the ground layer 92 by one side, and a power layer (power layer 96) disposed in contact with or adjacent to the other side of the lower signal layer 94.

In this case, in order to form a return current path of the lower signal layer 94, a metal electrically connecting the upper signal layer 90 and the power layer 96 between the upper signal layer 90 and the power layer 96 Plate or metal wire (93, 97) is provided, and a metal plate or metal wires 93a and 97a are provided between the top signal layer 90 and the ground layer 92 to electrically connect the top signal layer 90 and the ground layer 92. In addition, at the upper signal layer 90, at least one decoupling capacitor 91 (91a and 91b) is provided to equalize the voltage difference between the power layer 96 and the ground layer 92. Each of the at least one decoupling capacitors 91a and 91b is installed in electrical connection with the metal plates or the metal wires 93, 93a, 97, and 97a, and more specifically, the metal plates or the metal wires 93, 93a, 97, and 97a at the end of the upper signal layer 90 direction.

When each of the layers 90, 91, 94, and 96 is disposed as shown in FIG. 3, return current paths r90, r91, and r92 for a signal s91 transmitted between the components 90a and 90b are to be formed only at the ground layer 92 provided between the signal layers 90 and 94. In other words, the return current paths r90, r91, and r92 for signals transmitted between the plurality of components 90a and 90b through the upper signal layer 90 are formed in the ground layer 92 of the second layer. However, the return current paths r90, r93, r95, and r97 for a signal s92 transmitted through the lower signal layer 94 may be the metal plates or the metal wires 93, 93a, 97, and 97a, the power layer 96 and the decoupling capacitors 91a and 91b. Accordingly, the signal s91 transmitted through the upper signal layer 90 has a relatively good quality, but the signal s92 transmitted through the lower signal layer 94 and the return current paths r90, r93, r95, and, r97 is relatively long, and the quality thereof is deteriorated inevitably. Specifically, as shown in FIG. 3, when the printed circuit board 9 is provided, the signal s92 transmitted through the lower signal layer 94 is likely to cause overshoot or undershoot. In addition, crosstalk tends to be affected, and the quality is degraded.

On the other hand, as shown in FIGS. 1, 2 and 4, if the first ground 311 and the second ground 321 are formed on the second layer 310 and the fourth layer 320 adjacent to each of the first and third layers 100 and 200 of the printed circuit board 1, return current paths r11, r12, and r13 of a signal s11 transmitted from one circuit element 110c to another circuit element 110d through the third layer 200 may be formed to be relatively short. In addition, in the return current paths r11, r12, and r13, the signal to be fed back does not need to pass through the decoupling capacitors 108a and 108b. Therefore, the possibility of occurrence of overshoot and/or undershoot of the signal s11 transmitted between the circuit elements 110c and 110d is reduced, and the signal s11 is also strong against crosstalk, so that the quality of the signal s11 can be improved.

In addition, referring to FIG. 5, in the case of the conventional printed circuit board 9, when a relatively long wavelength signal wp (s1, i.e., a signal with a relatively low frequency) is transmitted through the lower signal layer 94, the return current paths r90, r91, and r91 are relatively short, and thus the transmitted signal may not be error-prone. However, when a relatively short wavelength signal we (i.e., a signal having a relatively high frequency) is transmitted through the lower signal layer 94, the longer the return current paths r90, r93, r95, and r97, the more likely the error occurs or is likely to occur in the transmitted signal. However, when the relatively short wavelength signal we (i.e., a signal having a relatively high frequency) is transmitted through the lower signal layer 94, the longer the return current paths r90, r93, r95, and r97, the more likely the error occurs or is likely to occur in the transmitted signal.

On the other hand, as shown in FIGS. 1, 2 and 4, in the case of the printed circuit board 1 provided with the first to fourth layers 100, 200, 310, and 320, the signal s11 having a relatively short wavelength is transmitted through the third layer 200, even if, since the return current paths r11, r12, and r13 are short, the same as a signal s10 of the relatively long wavelength signal wp, the signal s11 of a relatively short wavelength is also transmitted between the components 110a and 110b as appropriate, generally without errors.

When a signal s3 is transmitted through the lower signal layer 94 of the conventional printed circuit board 9, since the return current paths r90, r93, r95, and r97 are long, and the distance between the lower signal layer 94 and the ground layer 92 is far, the shape of the output and/or transmitted signal s3 may be distorted (s3a). For example, the increase or decrease of the signal s3 may be made smoothly differently than desired.

On the other hand, when a signal s4 is transmitted to the third layer 200 provided with the fourth layer 320, since the return current paths r90, r91, and r92 are shortened and the distance between the third layer 200 and the fourth layer 320 is shortened, the signal s4 can be output and/or transmitted in a desired form (s4a).

Furthermore, if the upper signal layer 90 of the conventional printed circuit board 9 is equipped with a memory whose operating speed is 3000 Mbps or more, as shown in FIG. 7, the signal corresponds to an increase in the operating speed of the memory since the frequency of the S-parameter changes rapidly (L1).

For example, when the frequency of the signal is in the range of 12 to 14 GHz, a sharp decrease in the S-parameter occurs. In other words, when using the conventional printed circuit board 9, an error occurs in the operation of the memory in accordance with the increase in the operating speed of the memory.

On the contrary, if each of the first layers 100 of the above-described printed circuit board 1 is equipped with a memory of 3000 Mbps or more, the S-parameter will be changed slowly. In particular, even when the transmission frequency of the signal is high, the S-parameter does not drop rapidly (L2). In other words, when the above-described printed circuit board 1 is used, the memory can operate more stably with shortening of the return current paths r11, r12, and r13 even if the operating speed of the memory is large.

Therefore, according to the above-described printed circuit board 1, even when high-speed processing of signals is required, each of the elements 110a and 110b or a device equipped with such printed circuit board 1 can be operated with high reliability without malfunction.

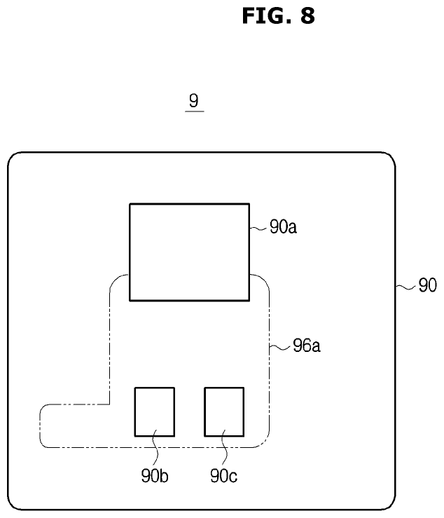

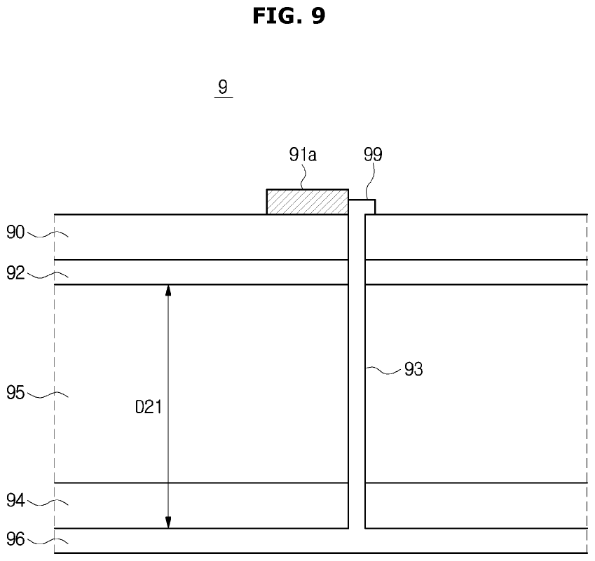

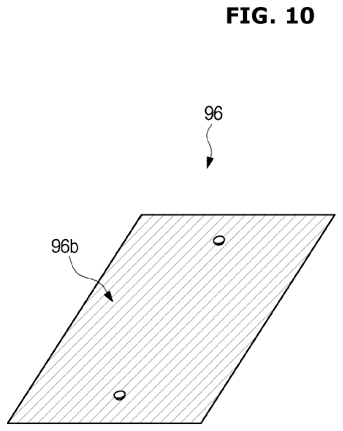

Hereinafter, the power supplier formed in the first layer will be described in more detail. FIG. 8 is a first diagram for describing a conventional printed circuit board having a power layer formed on a fourth layer. FIG. 9 is a second diagram for describing a conventional printed circuit board having a power layer formed on a fourth layer. FIG. 10 shows a conventional power supply layer.

Referring to FIGS. 8 and 9, the conventional printed circuit board 9 is formed by stacking the upper signal layer 90, the ground layer 92, the lower signal layer 94, and the power supply layer 96, and the predetermined circuit elements 90a, 90b, and 90c, for example, a processor chip or a memory element installed on one surface. A dielectric may be further formed between the ground layer 92 and the lower signal layer 94.

In the conventional printed circuit board 9, the circuit elements 90a, 90b, and 90c are supplied with the necessary power from the power supply layer 96 located at the bottom of the lower signal layer 94. The upper signal layer 90 of the conventional printed circuit board 9 is not provided with power suppliers 122 and 123 for supplying power, and does not receive the power required for operation from the power suppliers 122 and 123. More specifically, the circuit elements 90a, 90b, and 90c may be arranged at the bottom of the printed circuit board 9 via a metal plate or metal wire 96 electrically connected to the power supply layer 96. In this case, ends 99 of the metal plate or the metal wire 96 may be partially exposed to the outside as necessary, but this simply converts the power supplied from the lower power supply layer 96 to the circuit elements 90a, 90b, and 90c.

The power supply layer 96 may be implemented using a conductor.

For example, the conductor 96a may be formed over all or part of the circuit elements 90a, 90b, and 90c formed in the upper signal layer 90, as shown in FIG. 8. In other words, the conductor may be provided for some areas of the conductor 96a of the power supply layer 96 to deliver power to the circuit elements 90a, 90b, and 90c. In this case, another area of the power supply layer 96 may be formed in an insulator.

In another example, the conductor may be formed over the entire area of the power supply layer 96 as shown in FIG. 10. In other words, the entire area of the power supply layer 96 may be used to deliver power to the circuit elements 90a, 90b, and 90c. The power supply layer 96 may be formed corresponding to the entire area of the upper signal layer 90, in which case the area of the power supply layer 96 may be equal to or close to the area of the upper signal layer 90.

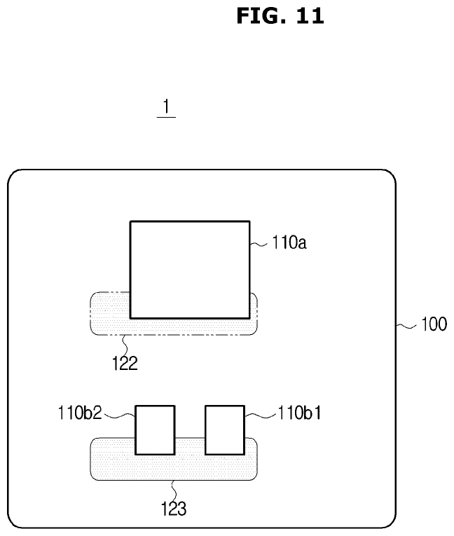

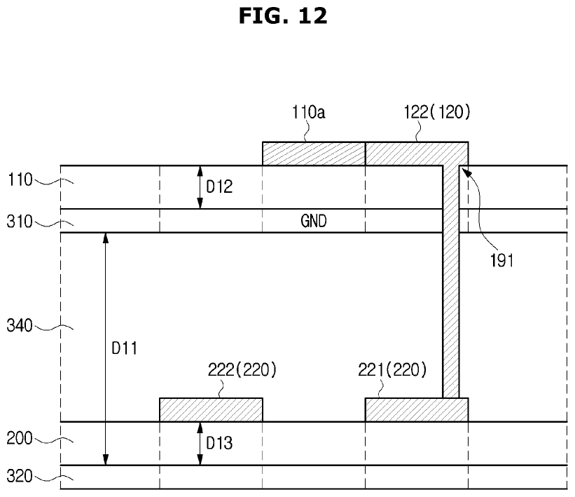

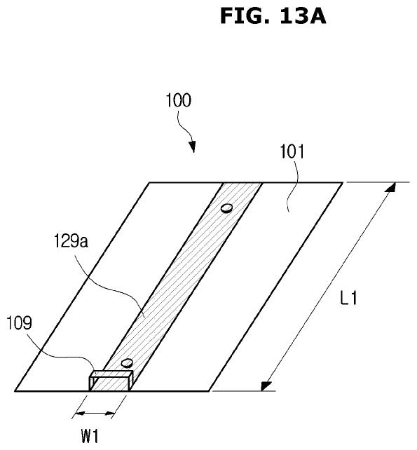

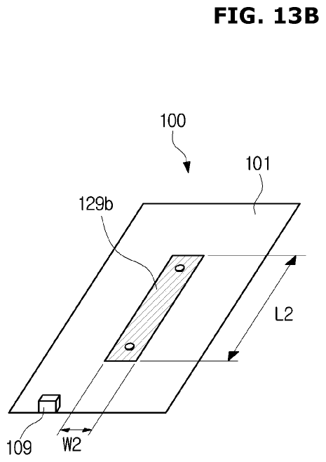

FIG. 11 is a plan view showing an example of a power supply unit formed in a first layer, FIG. 12 is a diagram for describing an electrical connection between a power supply unit of a first layer and a third layer, FIG. 13a is a diagram illustrating a first example of a power supplier, and FIG. 13b is a diagram illustrating a second example of a power supplier.

Referring to FIGS. 11 12, the printed circuit board 1 includes the first layer 100, the second layer 310, the third layer 200, and the fourth layer 320. One surface of the first layer 100 includes the circuit elements 110a and 110b and the first power suppliers 122 and 123 connected to each of the circuit elements 110a and 110b for supplying power to each of the circuit elements 110a and 110b. In other words, the printed circuit board 1 does not include the power supply layer 96 separately from the conventional printed circuit board 9. In the case of the printed circuit board 1, the operation and function of the power supply layer 96 is performed and provided by the first power suppliers 122 and 123 formed in the first layer 100.

The first power supplier may include a plurality of the first power suppliers 122 and 123 spaced apart from each other. The plurality of first power suppliers 122 and 123 may be formed on the one surface 101 of the first layer 100 in a predetermined pattern.

In example embodiments, each of the plurality of first power suppliers 122 and 123 may be formed to correspond to each of a circuit element, for example, the processor chip 110a and the memory element 110b. In other words, any one of the first power suppliers 122 and 123 may be formed in the first layer 100 to be electrically connected to any one of the corresponding circuit elements 110a and 110b. For example, different kinds of the first power suppliers 122 and 123 may be formed to correspond to each of the circuit elements 110a and 110b spaced apart from each other by a certain distance. Each of the first power suppliers 122 and 123 may provide power for operating each of the circuit elements 110a and 110b. According to an embodiment, each of the first power suppliers 122 and 123 may be provided to independently provide the power required for each of the circuit elements 110a and 110b.

According to an embodiment, as shown in FIG. 11, any one of the first power suppliers 123 may be provided to supply power to a plurality of circuit elements 110b1 and 110b2. In other words, one of the first power suppliers 123 may be electrically connected to the plurality of circuit elements 110b1 and 110b2 and installed in the first layer 100. In this case, the plurality of circuit elements 110b1 and 110b2 connected to any one of the power suppliers 123 may be the same type of circuit elements, for example, memory elements. In addition, the plurality of circuit elements 110b1 and 110b2 may be, for example, circuit elements provided in the first layer 100 adjacent to each other. In other words, one of the first power suppliers 123 may be electrically connected to the plurality of circuit elements 110b1 and 110b2 and installed in the first layer 100. In this case, the plurality of circuit elements 110b1 and 110b2 connected to any one of the power suppliers 123 may be the same type of circuit elements, for example, memory elements. In addition, the plurality of circuit elements 110b1 and 110b2 may be, for example, circuit elements provided in the first layer 100 adjacent to each other.

Each of the first power suppliers 122 and 123 may be formed in whole or in part between the circuit elements 110a and 110b. For example, the power supplier 122 for supplying power to the processor 110a may be formed around the processor 110a and may be formed between the processor 110a and the memory devices 110b1 and 110b2. In another example, the power supplier 123 for supplying power to the memory devices 110b1 and 110b2 may be formed around the memory devices 110b1 and 110b2, and the processor 110a and the memory devices 110b1 and 110b2 In addition, each of the first power suppliers 122 and 123 may be formed between other circuit elements, for example, a diode or a capacitor. In this case, the first power suppliers 122 and 123 may be provided to extend through the other circuit elements to the processor 110a or the memory element 110b.

Referring to FIG. 13a, the first power supplier 129a may be installed extending from one end to the other end in the length direction of the one surface 101 of the first layer 100. In this case, a width w1 of the first power supplier 129a may be relatively smaller than the width of the first layer 100, and a length 11 may be equal to or close to the length of the first layer 100. In this case, the power receiver 109 may be installed at one end of the first power supplier 129a to transmit power to the first power supplier 129a.

In addition, referring to FIG. 13b, the first power supplier 129b may be installed only for a portion of the one surface 101 of the first layer 100. A width w2 and an area 12 of the first power supplier 129b may be significantly smaller than the width and area of the first layer 100, respectively. In addition, the first power supplier 129b may be installed in an area other than a boundary of the first layer 100. In this case, the first power supplier 129b may be electrically connected to the second power supplier 220 installed in the third layer 200, and the second power supplier 220 may be electrically connected to the power receiver 109. Accordingly, the first power supplier 129b may receive the necessary power from the power receiver 109.

Referring to FIG. 12, the power supplier, that is, the second power supplier 220: 221 and 222 may also be installed in the third layer 200. The second power supplier 220: 221 and 222 may be connected to the first power suppliers 122 and 123 through the metal plate or the metal line 128 provided through the first via hole 191. Accordingly, the current flowing from one of the first power suppliers 122 and 123 and the second power suppliers 221 and 222 may flow to the other, and the circuit elements 110a and 110b may be supplied with power using at least one of the first power suppliers 122 and 123 and the second power supplier 220.

The second power supplier 220 may be electrically connected to at least one of the plurality of first power suppliers 122 and 123 through the metal plate or the metal line 128. In other words, some of the plurality of first power suppliers 122 and 123 may be designed to be electrically connected to the second power supplier 220 and the other part of the plurality of first power suppliers 122 and 123 may be designed not to be electrically connected to the second power supplier 220.

In addition, the second power supplier 220 may also include a plurality of the second power suppliers 221 and 222 separated from each other. At least one of the plurality of second power suppliers 221 and 222 may be electrically connected to at least one of the first power supplier 120 or the plurality of first power suppliers 122 and 123 through the metal plate or the metal line 128.

Referring to FIGS. 11 to 13b, the power suppliers 122 and 123 formed in the first layer 100 and occupying the first layer 100 are relatively smaller in size than the portion occupied by the power supply layer 96 of the printed circuit board 9. For example, as shown in FIG. 8, the power supply layer 96 of the conventional printed circuit board 9 is formed over the entire upper signal layer 90, or the circuit elements 91a, 91c, and 91b, or it is installed continuously over all or part of. In other words, the difference between the area of the upper signal layer 90 and the area of the power supply layer 96 is little or relatively small. On the other hand, the power suppliers 122 and 123 of the first layer 100 may be installed only in a portion where the circuit elements 110a and 110b are absent as described above, so that the difference between the area of the first layer 100 and the area of the power supply layer 96 is relatively large. In other words, the area of the power suppliers 122 and 123 is considerably smaller than the area of the first layer 100. In addition, when the plurality of power suppliers 122 and 123 formed in the first layer 100 are separated and spaced apart from each other in correspondence with the circuit elements 110a and 110b as described above, the plurality of power suppliers 122 and 123 may be installed in a relatively narrower area than the power layer 96 formed over all or part of the circuit elements 91a, 91c and 91b. Thus, the power suppliers 122 and 123 formed in the first layer 100 have a relatively smaller area than the power layer 96 of the conventional printed circuit board 9.

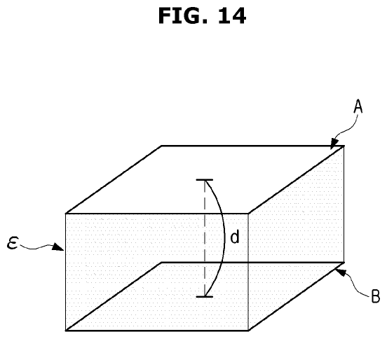

FIG. 14 is a diagram for describing impedance between a power plane and a ground.

In designing the conventional printed circuit board 9, a magnitude of impedance Z is typically inversely proportional to the area of the power layer 96. In order to improve the performance of the printed circuit board 9 and an apparatus using the same, it has been common to increase the area of the power layer 96.

In the case of the printed circuit board 1 described above, the power suppliers 122 and 123 formed in the first layer 100 have a relatively smaller area than the power layer 96 of the conventional printed circuit board 9. Therefore, it may be seen that the impedance Z is increased to deteriorate the performance. However, in the above-described printed circuit board 1, the impedance Z does not increase greatly despite the small area of the power suppliers 122 and 123.

Specifically, the capacitor impedance Z is given by Equation 1 below.

$$Z = \frac{1}{j ω C} \qquad [ Equation 1 ]$$

Where Z is the impedance, w is the angular velocity (i.e., the frequency multiplied by 2n), and j is the phase of the capacitor. C means the capacitance of the capacitor. In other words, when the other conditions are the same, the impedance Z is inversely proportional to the magnitude of the capacitance C.

In addition, the capacitance C may be given by Equation 2 below with reference to FIG. 14.

$$C = \frac{ɛ \cdot P a}{d} \qquad [ Equation 2 ]$$

Where C is the capacitance, c is the dielectric constant of the dielectric, Pa is the area of anode plates A and B, and d is the distance between the anode plates A and B. In other words, the capacitance C decreases as the distance between the positive anode plates A and B increases, and increases as the area of the positive anode plates A and B increases. Therefore, even if the area of the anode plates A and B is reduced, the capacitance C may be maintained or increased if the distance d between the anode plates A and B is sufficiently reduced. More specifically, the capacitance C may be the same when the distance d between the anode plates A and B decreases in proportion to the decrease in the area of the anode plates A and B.

Therefore, when the contents of Equations 1 and 2 are combined, the value of the impedance Z can be determined corresponding to a ratio between an area d of the anode plates A and B and the distance d between the anode plates A and B (Pa/d), and it can be seen that despite the reduction of the area Pa of the anode plates A and B, it may have the same value or a smaller value depending on the reduction of the distance d.

Referring to FIGS. 9 and 12, the area of the power supply layer 96 of the conventional printed circuit board 9 is relatively larger than that of the first power supplier 120 and/or the second power supplier 220. In addition, a distance d21 between the ground layer 92 and the power supply layer 96 of the conventional printed circuit board 9 is relatively larger than a distance d12 between the first power supplier 120 and the second layer 310 and/or the distance d12 between the second power supplier 220 and the fourth layer 320.

In this case, using the ratio between the distance d21 between the ground layer 92 and the electrode layer 96, and any one of the distance d12 between the first power supplier 120 and the second layer 310 and the distance d12 between the second power supplier 220 and the fourth layer 320, the area of the first power supplier 120 and/or the second power supplier 220 can be obtained in which the impedance of the printed circuit board 1 can be equal to or close to the impedance of the conventional printed circuit board 9.

Specifically, an impedance Zp of the conventional printed circuit board 9 and an impedance Ze of the printed circuit board 1 according to the exemplary embodiment may be given by Equations 3 and 4, respectively.

$$\begin{matrix}{Z}_{p} = \frac{1}{j ω \frac{ɛ \cdot {P}_{p}}{{d}_{p}}} & [ Equation 3 ] \\ {Z}_{e} = \frac{1}{j ω \frac{ɛ \cdot {P}_{e}}{{d}_{e}}} & [ Equation 4 ]\end{matrix}$$

In Equations 3 and 4, Zp denotes the impedance of the conventional printed circuit board 9, and Ze denotes the impedance of the printed circuit board 1 according to one embodiment. ω, j and ε refer to the angular velocity and the phase of the capacitor as described above. Pp is the area of the electrode layer 96, Pe is the area of the first power supplier 120 and/or the second power supplier 220, dp is the distance between the ground layer 92 and the electrode layer 96, and de is the distance between the first power supplier 120 and the second layer 310, and/or the distance between the second power supplier 220 and the fourth layer 320.

If the impedance Zp of the printed circuit board 9 and the impedance Ze of the printed circuit board 1 according to the embodiment are the same, Equations 3 and 4 may be given as Equation 5 below.

$${P}_{e} = {P}_{p} \frac{{d}_{e}}{{d}_{p}} \qquad [ Equation 5 ]$$

In other words, when the area of the first power supplier 120 and/or the second power supplier 220 is determined by reducing the area of the electrode layer 96 by a ratio (de/dp), it is equal to the impedance Zp of the printed circuit board 9 and the impedance Ze of the printed circuit board 1 according to the embodiment.

On the other hand, a distance d11 between the second layer 310 and the fourth layer 320 in the printed circuit board 9 may correspond to the distance d21 between the ground layer 92 and the power supply layer 96 of the conventional printed circuit board 9. Therefore, by using the ratio of at least one of the distance d12 between the first power supplier 120 and the second layer 310, the distance d12 between the second power supplier 220 and the fourth layer 320, and the distance d11 between the second layer 310 and the fourth layer 320, the area of the first power supplier 120 and/or the second power supplier 220 may be calculated such that the impedance of the printed circuit board 1 may be equal to or approximate to the impedance of the conventional printed circuit board 9.

As such, when the first power supplier 120 and/or the second power supplier 220 are given an appropriate area, the impedance does not increase significantly and may be the same or lower. Therefore, even if the printed circuit board 1 according to the embodiment is used, the performance degradation due to the impedance increase does not occur.

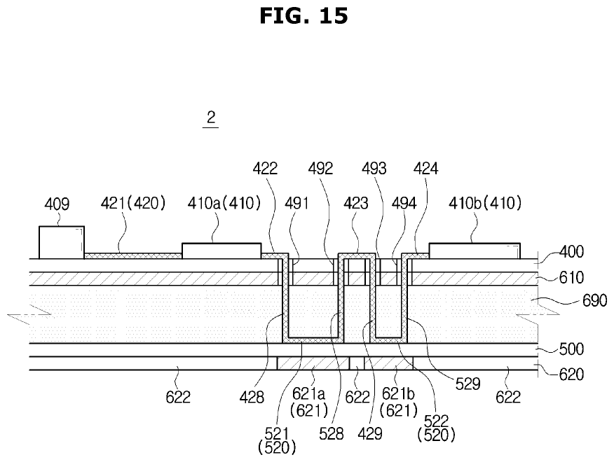

FIG. 15 is a cross-sectional view of a modification of a printed circuit board.

As shown in FIG. 15, a printed circuit board 2 may include a first layer 400, a second layer 610, a third layer 500, and a fourth layer 620 sequentially stacked on each other. As shown in FIGS. 1 and 2, the first layer 400 is provided such that at least one of circuit elements 409 and 410 and the first power supplier 420 can be formed on one surface thereof. The second layer 610 is formed to be in contact with or close to the first layer 100, but is provided to provide a return current path for the signal transmitted from the first layer 400. A second power supplier 420 is formed in the third layer 500, and the fourth layer 620 is formed in contact with or in proximity to the third layer 500. There may be a dielectric between the second layer 610 and the third layer 500.

The at least one circuit elements 409 and 410 may include various circuit elements that can be installed in the first layer 400. For example, it may include a processor chip 410a, a memory device 410b, and a power receiver 409. In addition, the at least one circuit elements 409 and 410 may include a capacitor, an inductor, a diode, a transistor, a light tube, and/or an amplifier.

The first power supplier 420 provides power to the at least one circuit elements 409 and 410 for the operation of the at least one circuit elements 409 and 410 (410a and 410b). The first power supplier 120 can be implemented using a metal plate or a metal wire capable of transmitting current such as copper. In addition, at least one of one surface (externally exposed surface) and the other surface of the first layer 400 may be formed such that all or part of the first layer 400 is exposed to the outside or not to the outside.

The first power supplier 420 may include a plurality of first power suppliers 421, 422, 423, and 424 separated and spaced apart from each other according to an embodiment. Each of the plurality of first power suppliers 421, 422, 423, and 424 supplies power to each of the corresponding the at least one circuit elements 409, 410a, and 410b or between the circuit elements 409, 410a, and 410b. It can provide a transmission path of the electrical signal to be transmitted.

Specifically, for example, the first portion 421 of the first power supplier 420 electrically connects the power receiver 409 and any one of the circuit elements 410a (e.g., a processor), the second portion 422 is formed between the processor 410a and any one via hole 491 (hereinafter, referred to as ‘first via hole’), the third portion 423 is formed between another via hole 492 (hereinafter, referred to as ‘second via hole’) and another via hole 493 (hereinafter, referred to as ‘third via hole’), and the fourth portion 424 may be provided to connect another via hole 494 (hereinafter, referred to as ‘fourth via hole’) and another one of the circuit elements 410b (e.g., a memory element).

The above-described first power supplier 420 (which may include a plurality of the first power suppliers) may be installed in the first layer 400 in a predetermined pattern, for example, may have a shape of a flat plate. However, the area may be formed smaller than the area of the second layer 610.

In the second layer 610, a device capable of transmitting an electrical signal, such as a plurality of conductive wires or circuits, may be provided through the second layer 610. As described above, the second layer 610 may provide a return current path for the electrical signal transmitted to the first layer 400.

The second power supplier 520 may be further installed in the third layer 500. The second power supplier 520 is electrically connected to the first power supplier 420 through predetermined conductors 428, 528, 429, and 522.

The fourth layer 620 may, in one embodiment, only provide some zones 621 (621a, 621b) to serve as a ground. In other words, another region of the fourth layer 620 may be provided to function as the ground. In this case, each of the partial zones 621a and 621b providing the function of grounding may be spaced apart from each other.

If grounding is provided only in some of the zones 621a and 621b, a plurality of second power suppliers 521 and 522 may be formed in the third layer 500 to correspond to the partial zones 621a and 621b of the fourth layer 620.

Each of the plurality of second power suppliers 521 and 522 may be provided such that its area is relatively smaller than the corresponding partial zones 621a and 621b of the fourth layer 620.

Each of the second power suppliers 521 and 522 is electrically connected to at least one of the plurality of first power suppliers 422, 423, and 424, and receive electrical signals from at least one of the plurality of first power suppliers 422, 423, and 424 and/or transmit electrical signals to at least one of the plurality of first power suppliers 422, 423 and 424.

For example, the current output from the processor 410a may be transmitted to any one of the second power suppliers 520 and 521 through the second portion 422 and the conductor 428 of the first power supplier 420. In addition, the current transmitted from any one of the second power suppliers 520 and 521 is transmitted to the third portion 423 of the first power supplier 420 through the conductor 528 and the current delivered to the third portion 423 of the first power supplier 420 may be transferred back to the other one 522 of the second power supplier 520 through the conductor 429. In addition, the current delivered from the other one 522 of the second power supplier 520 is transferred to the fourth portion 424 of the first power supplier 420 via the conductor 529 and may be transferred to the memory device 410b in contact with the fourth portion 424. Accordingly, the current supplied through the power receiver 409 of the first layer 400 may be transferred to the memory device 410b via the first layer 400 and the third layer 500 two or more times. Although FIG. 15 illustrates an embodiment in which current is delivered via the first layer 400 and the third layer 500 twice, the number of passes through the signal layers 400 and 500 is not limited thereto. For example, the printed circuit board 2 may be designed such that the current passes through the first layer 400 and the third layer 500 three or more times, and then is transferred to any one of the circuit elements 410b. For example, the printed circuit board 2 may be designed such that the current passes through the first layer 400 and the third layer 500 three or more times, and then is transferred to any one of the circuit elements 410b.

As described above, when the fourth layer 620 provides a grounding function only in each of the plurality of zones 621a and 621b spaced apart from each other, correspondingly, the fourth layer 620 has a smaller area than some of the zones 621a and 621b spaced apart from each other. Since the plurality of second power suppliers 521 and 522 are formed in the third layer 500, the quality of the signal through the second power suppliers 521 and 522 may be further improved. In this case, transfer of current between the plurality of second power suppliers 521 and 522 spaced apart from each other may be enabled by using any one of the first power suppliers 423 of the first layer 400.

Since a detailed description of each configuration shown in FIG. 15 has already been described with reference to FIGS. 1 to 14, detailed descriptions thereof will be omitted below.

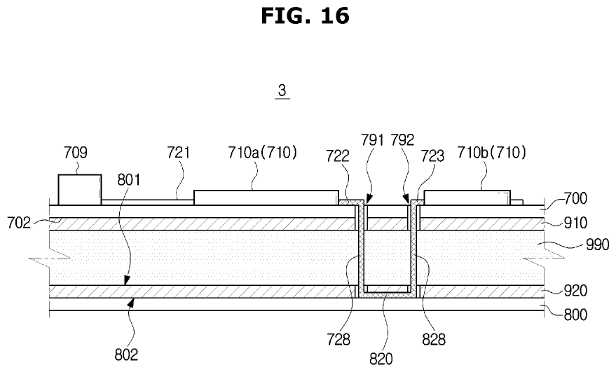

FIG. 16 is a sectional view of another modification of a printed circuit board.

As shown in FIG. 16, a printed circuit board 3 according to another exemplary embodiment may include a plurality of stacked layers 700, 800, 910, and 920.

In this case, the printed circuit board 3 includes the first layer 700 on which at least one circuit element 709, 710: 710a and 710b and a first power supplier 720: 721, 722, and 723 are formed, the second layer 910 formed in contact with or in proximity to the first layer 700, the third layer 800 where a second power supplier 820 is formed, and the fourth layer 920 formed in contact with or adjacent to the third layer 800. In this case, the fourth layer 920 may be formed between the second layer 910 and the third layer 800. In other words, when compared with the printed circuit board 1 shown in FIGS. 1 and 2, the positions of the third layers 200 and 800 and the fourth layers 320 and 920 may be interchanged with each other. Accordingly, the first layer 700, the second layer 910, the fourth layer 920, and the third layer 800 are sequentially stacked.

In this case, a metal plate or a metal line 728 passing through a first via hole 791 and connecting the first layer 700 and the third layer 800, a metal plate or a metal line 828 connecting the first layer 700 and the third layer 800 through a second via hole 792 may extend through the fourth layer 920 to the third layer 800.

The second power supplier 820 may be formed in the third layer 800 to transmit an electrical signal, and according to an embodiment, the second power supplier 820 may be formed in the direction of the fourth layer 920 and/or in a direction opposite to the fourth layer 920. In addition, a predetermined circuit element may be further provided in the third layer 800 in a direction opposite to the fourth layer 920 and/or in a direction opposite to the fourth layer 920.

The printed circuit board 3 disposed as described above may also obtain the same or similar effects as the printed circuit board 1 described with reference to FIGS. 1 to 15. Further, according to the embodiment, it is apparent that the printed circuit board 2 described with reference to FIG. 15 is applicable to the printed circuit board 3 shown in FIG. 16.

Since other elements have already been described in detail, detailed descriptions thereof will be omitted below.

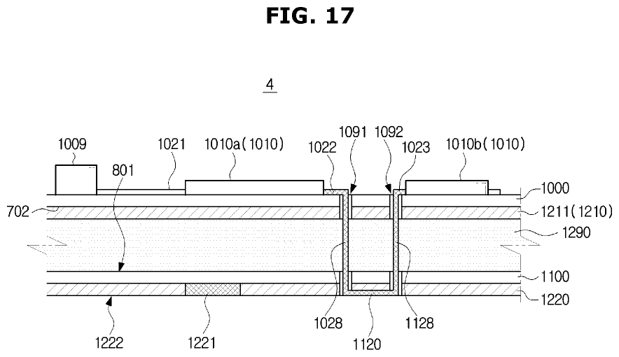

FIG. 17 is a sectional view of another modification of a printed circuit board.

Referring to FIG. 17, a printed circuit board 4 may include a first layer 1000, a second layer 1210, a third layer 1100, and a fourth layer 1220 in one embodiment. Each of the layers may be formed by being stacked on each other. In this case, a dielectric 1290 may be further formed between the second layer 1210 and the third layer 1100.

As described above, circuit elements 1009 and 1010 such as the power receiver 1009, a processor 1010a, a memory 1010b, and the like may be formed in the first layer 1000, and the circuit elements 1009 and 1010. Also, signal lines (not shown) and the like for signal transmission therebetween may be formed. If necessary, a first power supplier 1020: 1021, 1022, and 1023 may be further installed in the first layer 1000 to supply power to the circuit elements 1009 and 1010.

A first ground 1211 may be formed in the second layer 1210. The first ground 1211 may be formed in the entirety of the second layer 1210 or may be formed in a portion of the second layer 1210.

Signal lines (not shown) may be provided in the third layer 1100. According to an embodiment of the present disclosure, a power supplier may not be formed in the third layer 1100, as described above. However, in the third layer 1100, a hole may be further formed for conductors 1028 and 1128 for connecting a third power supplier 1120 formed in the fourth layer 1220 and the first power suppliers 1022 and 1023 of the first layer 1000 to penetrate.

A second ground 1221 may be formed in the fourth layer 1220. The second ground 1221 may be installed to correspond to signal lines or the power suppliers 1021, 1022, 1023, and 1120, for example, the signal line or the power suppliers 1021, 1022, 1023, and 1120 may be formed on at least one position corresponding to the installed position.

The third power supplier 1120 may be further installed in the fourth layer 1220. For example, the third power supplier 1120 may be formed to be exposed to one surface 1222 exposed to the outside of the fourth layer 1220. In other words, the third power supplier 1120 may be installed in the fourth layer 1220 together with the second ground 1221. In this case, the third power supplier 1120 may be installed adjacent to the second ground 1221, or may be installed spaced apart by a predetermined distance or more. In other words, the third power supplier 1120 may be installed in the fourth layer 1220 together with the second ground 1221. In this case, the third power supplier 1120 may be installed adjacent to the second ground 1221, or may be installed spaced apart by a predetermined distance or more. When the third power supplier 1120 is formed in the fourth layer 1220, the first power suppliers 1021, 1022, and 1023 of the first layer 1000 may be omitted or minimally installed. For example, the first power supplier 1021 is formed to be exposed to the outside of the first layer 1000 only around the signal receiver 1009, and the first power supplier 1021 is electrically connected to the third power supplier 1120 through the direct conductor 1028. The third power supplier 1120 transmits an electrical signal at the fourth layer 1220. The electrical signal is transmitted to the circuit elements 1010a and 1010b through the conductor 1128 connecting the circuit elements 1010a and 1010b and the third power supplier 1120.

According to the above, even when there are many parts 1010 to be mounted on the first layer 1000 and the space for forming the first power suppliers 1021, 1022, and 1023 is not sufficiently formed on the outer surface of the first layer 1000, it is possible to install the third power supplier 1120 on the printed circuit board 4 sufficient to power the component 1010.

Hereinafter, the outline of an example to which the above-described printed circuit boards 1 to 4 are applied will be described.

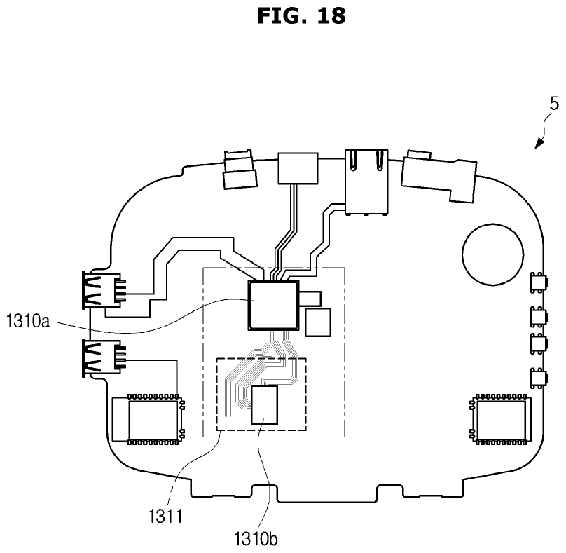

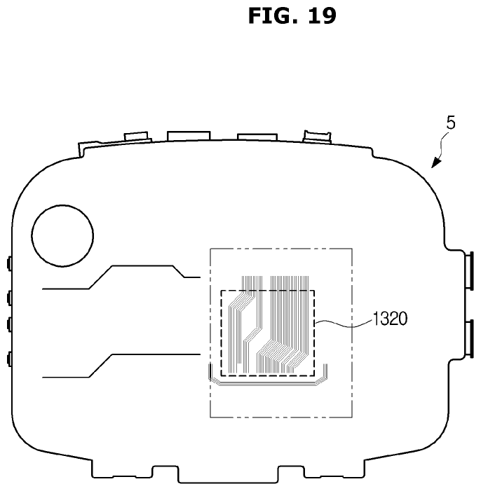

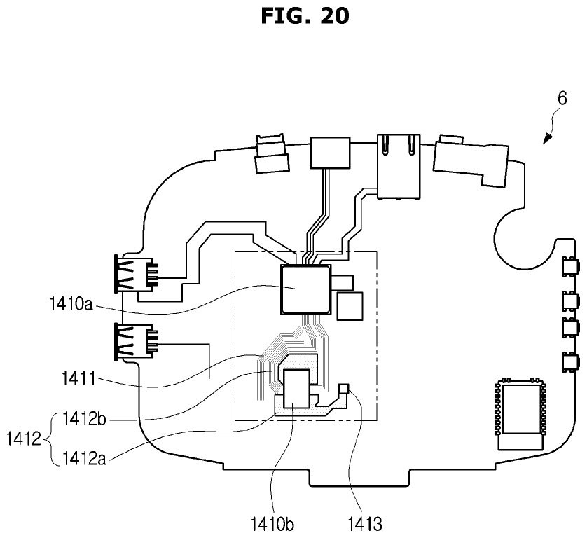

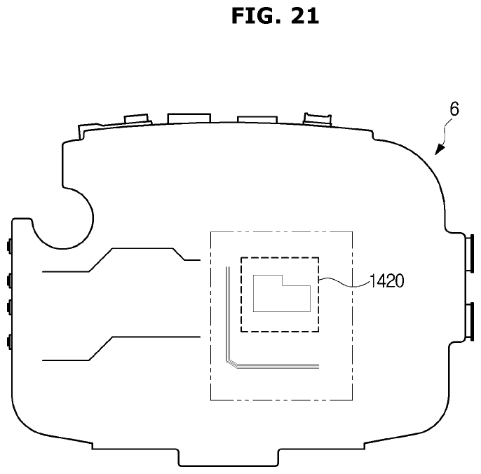

FIG. 18 is a plan view of an example of a conventional printed circuit board, FIG. 19 is a rear view of an example of a conventional printed circuit board, FIG. 20 is a plan view of one embodiment of the above-described printed circuit board and FIG. 21 is a rear view of one embodiment of the above-described printed circuit board. FIGS. 18 and 19 show the outline of a printed circuit board 5 embedded in a conventional set top box, and FIGS. 20 and 21 illustrate the appearance of a printed circuit board 6 according to any of the embodiments described above, which may be embedded in a set top box.

As shown in FIGS. 18 and 19, the conventional printed circuit board 5 includes a circuit element such as a processor 1310a or a memory chip 1310b and a signal line 1311 for connecting them to one surface thereof, and a signal line 1320 or a power plate formed at a position corresponding to each of the circuit elements 1310a and 1310b and/or the signal line 1311 on the other surface opposite to one surface.

Referring to FIG. 20, in the printed circuit board 6 according to any one of the above-described embodiments, a circuit element such as a processor 1410a or a memory chip 1410b and a signal line 1411 for connecting them are formed on one surface thereof. For example, a power supplier 1412 is formed around the memory chip 1410b. In this case, the power supplier 1412 may be divided into two separate portions 1412a and 1412b so that the signal line 1411 connected by the processor 1410a may be appropriately connected with the memory chip 1410b.

In addition, referring to FIG. 21, in the printed circuit board 6 according to any one of the above-described embodiments, a ground 1420 is formed at a portion opposite to a portion where the processor 1410a, the memory chip 1410b, and the signal line 1411 are provided on the other surface opposite to one surface. In other words, when compared with the conventional printed circuit board 5 of FIG. 19, the conventional printed circuit board 5 has the signal line 1320 or the power plate at a portion corresponding to the processor 1410a, the memory chip 1410b, or the like. In the printed circuit board 6 according to any of the above-described embodiments, the ground 1420 is formed at the same position so that no special signal line or the like is formed.

As described above, the printed circuit board 6 according to any one of the embodiments described above includes a second layer having a first ground formed between one surface and the other surface, and a third layer on which signal lines and the like can be arbitrarily installed.

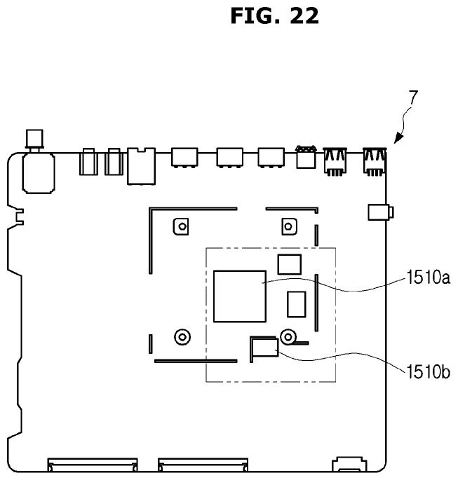

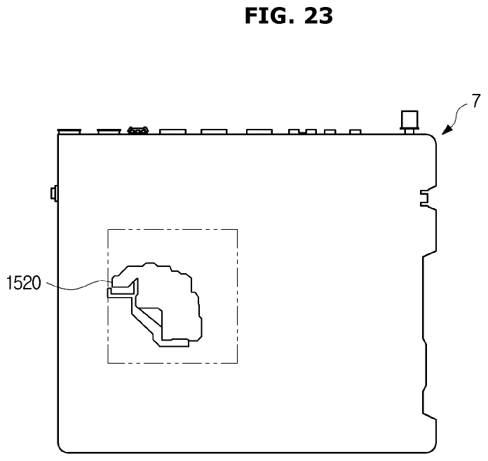

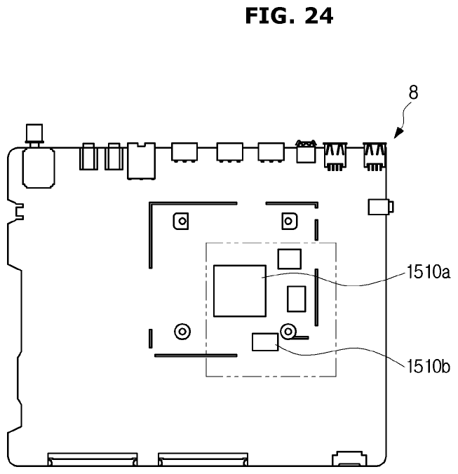

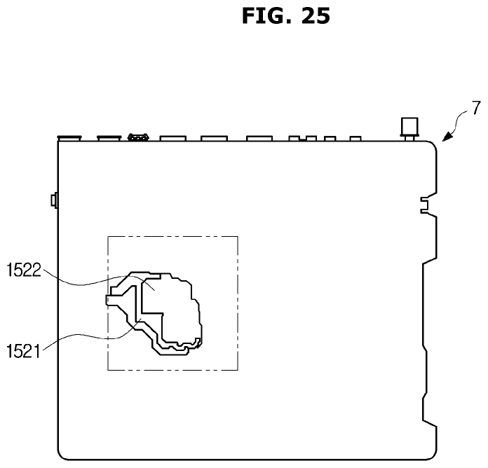

FIG. 22 is a plan view of another example of a conventional printed circuit board, FIG. 23 is a rear view of another example of a conventional printed circuit board, FIG. 24 is a plan view of one embodiment of the above-described printed circuit board, and FIG. 25 is a rear view of one embodiment of the above-described printed circuit board.

FIGS. 22 and 23 show the appearance of a printed circuit board 7 embedded in a conventional digital television, and FIGS. 24 and 25 show the outline of a printed circuit board 8 according to any of the embodiments described above and mountable inside the display device.

Referring to FIGS. 22 and 23, in the conventional printed circuit board 7, a circuit element such as a processor 1510a or the memory chip 1310b may be mounted on one surface thereof, and a signal line (not shown) for connecting them may be exposed to the outside as necessary and formed. In addition, a power plate 1520 for supplying power to the circuit elements 1510a and 1510b is formed on the other surface of the printed circuit board 7 so as to face the circuit elements 1510a and 1510b. In addition, the power plate 1520 for supplying power to the circuit elements 1510a and 1510b is formed on the other surface of the printed circuit board 7 so as to face the circuit elements 1510a and 1510b. In addition, the power plate 1520 for supplying power to the circuit elements 1510a and 1510b is formed on the other surface of the printed circuit board 7 so as to face the circuit elements 1510a and 1510b.

Meanwhile, referring to FIG. 24, in the printed circuit board 8 according to any one of the above-described embodiments, a circuit element such as the processor chip 1510a, the memory chip 1510b, or the like is provided on one surface thereof. As a result, signal lines (not shown) for connecting them may be exposed to the outside. In this case, the above-described power supplier 1412 of FIG. 20 may not be formed on one surface of the printed circuit board 8.

Referring to FIG. 25, a power supplier 1521 may be formed on the other side of the printed circuit board 8. The power supplier 1521 may be installed at a position capable of appropriately supplying power to the processor chip 1510a or the memory chip 1510b. For example, the power supplier 1521 may be formed in a predetermined shape at one position of the other surface located opposite to one position of one surface on which the processor chip 1510a or the memory chip 1510b is installed.

In addition, a second ground 1522 may be formed on the other surface of the printed circuit board 8. In this case, the power supplier 1521 may be formed adjacent to the second ground 1522, as shown in FIG. 25. For example, the second ground 1522 may be formed in one region of the other surface of the printed circuit board 8, and the power supplier 1521 may be burned in a line having a predetermined shape along the boundary of the second ground 1522. Of course, according to the embodiment, the power supplier 1521 may be set to be spaced apart from the second ground 1522 by a predetermined distance or more.

As described above, the printed circuit board 8 according to any one of the embodiments described above includes a second layer having a first ground formed between one surface and the other surface, and a third layer on which signal lines and the like can be arbitrarily installed.

The above-described printed circuit boards 1 to 4, 6, and 8 may also be applied to various types of printed circuit boards. For example, the above-mentioned printed circuit board may be a rigid printed circuit board, a flexible printed circuit board, or may be a flexible printed circuit board.

The printed circuit boards 1 to 4, 6, and 8 described above can be employed in predetermined electronic devices. In this case, the electronic device includes a first circuit element, a second circuit element capable of receiving electrical signals from the first circuit element, and a printed circuit board on which the first circuit element and the second circuit element are mounted. The printed circuit board on which the first circuit element and the second circuit element are mounted is provided to include the first layer, the second layer, the third layer, and the fourth layer described with reference to FIGS. 1 to 25. As described above, the first layer and the second circuit element can be installed in the first layer, and it may also include a power supplier for supplying power to at least one of the first circuit element and the second circuit element.

Here, the predetermined electronic device may include a display device. For example, the display device may include various electronic devices to display a digital television, a monitor device, a smartphone, a tablet PC, an electronic blackboard, a navigation device, a portable game machine, an electronic billboard, and/or other images.

The predetermined electronic device may be a desktop computer, a laptop computer, a server computer, a set-top box, a home appliance (which may include a vacuum cleaner, a refrigerator, an air conditioner, a microwave, an oven, a washing machine, etc.), a game machine (which may include a home game machine or a commercial game machine), an industrial machine or a robot, a vehicle, construction equipment, and/or an aircraft.

In addition to these, according to the designer's choice or consideration, an example of the predetermined electronic device described above is various electronic devices in which a printed circuit board on which a circuit element (for example, a processor chip, a memory chip, etc.) is mounted or installed.

While various embodiments of the printed circuit board have been described above, the embodiment of the printed circuit board is not limited only to the above. Other printed circuit boards that can be modified on the basis of the above-described embodiments by those skilled in the art may also be an embodiment of the above-described printed circuit boards. For example, even if the described structures, devices, circuits, components, or the like are combined in a different form from the described method, or replaced by other components or equivalents, the embodiment of the above-described printed circuit board may be used.

1. A printed circuit board comprising:
a first layer in which a first signal transmission path is formed;
a second layer disposed in one surface direction of the first layer and including a first ground for providing a return current path for a signal transmitted from the first layer;
a third layer in which a second signal transmission path is formed; and
a fourth layer disposed in the other surface direction of the third layer and including a second ground for providing a return current path for a signal transmitted from the third layer.

2. The printed circuit board of claim 1 further comprising:
a plurality of circuit elements installed in the first layer; and
at least one of a first power supplier installed in the first layer for supplying power to at least one of the plurality of circuit elements;
a second power supplier installed in the third layer for supplying power to at least one of the plurality of circuit elements; and
a third power supplier installed in the fourth layer for supplying power to at least one of the plurality of circuit elements.

3. The printed circuit board of claim 2, wherein the first power supplier has a flat plate shape of a predetermined pattern.

4. The printed circuit board of claim 2, wherein all or a portion of the first power supplier is disposed between at least two of the plurality of first circuit elements.

5. The printed circuit board of claim 2, wherein the area of the first power supplier is the same as the area of the first ground or smaller than the area of the first ground.

6. The printed circuit board of claim 5, wherein the area of the first power supplier corresponds to a ratio of distance between the first layer and the second layer and distance between the second layer and the fourth layer.

7. The printed circuit board of claim 2, wherein the first power supplier includes a plurality of power suppliers spaced apart from each other, and wherein the plurality of power suppliers is electrically connected to each of the corresponding plurality of circuit elements to supply power to each of the plurality of circuit elements.

8. The printed circuit board of claim 2, wherein at least two of the first power supplier, the second power supplier, and the third power supplier are electrically connected to each other.

9. The printed circuit board of claim 2, wherein the size of the second power supplier is equal to or smaller than the size of the fourth layer.

10. The printed circuit board of claim 2, wherein the first power supplier is installed to be exposed to the outside in the other surface direction of the first layer.

11. The printed circuit board of claim 2, wherein the plurality of circuit elements includes:
a transmitting element for transmitting the signal; and
a receiving element receiving the signal transmitted from the transmitting element.

12. The printed circuit board of claim 2, wherein the plurality of circuit elements includes a processor chip and a memory chip.

13. The printed circuit board of claim 12, wherein the memory chip has an operation speed of 3000 Mbps or more.

14. The printed circuit of claim 1, wherein the first layer and the third layer are electrically connected and the signal is transmitted from the first layer to the third layer.

15. The printed circuit of claim 14, wherein the signal transmitted from the first layer to the third layer is transmitted from the third layer to the first layer after passing the second signal transmission path.
